(19) United States
(12) Patent Application Publication
(10) Pub. No.: US 2025/0221076 A1
(43) Pub. Date: Jul. 3, 2025

(54) IMAGE SENSOR

(71) Applicant: Samsung Electronics Co., Ltd., Suwon-si (KR)

(72) Inventors: Sanghoon KIM, Suwon-si (KR); Hyeji SHIN, Suwon-si (KR)

(73) Assignee: Samsung Electronics Co., Ltd., Suwon-si (KR)

(21) Appl. No.: 18/795,615

(22) Filed: Aug. 6, 2024

(30) Foreign Application Priority Data
Jan. 3, 2024 (KR) 10-2024-0000726

(51) Int. Cl. H01L 27/146

(52) U.S. Cl. CPC H10F 39/807; H10F 39/011

(57) ABSTRACT

An image sensor includes a substrate including a plurality of pixel areas, a pixel isolation film disposed in the substrate, the pixel isolation film separating the plurality of pixel areas from each other, and each pixel area of the plurality of pixel areas including, a first impurity region, a second impurity region around the first impurity region in a first direction, and an element isolation film between the first impurity region and the second impurity region in the first direction, the element isolation film including, a first insulating layer, a second insulating layer on a first portion of the first insulating layer and formed of a material different from a material of the first insulating layer, and a third insulating layer, a portion of the third insulating layer on the second insulating layer, and a portion of the third insulating layer directly in contact with the first insulating layer.

### CROSS-REFERENCE TO RELATED APPLICATION(S)

This U.S. non-provisional application claims the benefit of priority under 35 USC 119(a) to Korean Patent Application No. 10-2024-0000726 filed on Jan. 3, 2024 in the Korean Intellectual Property Office, the entire disclosure of which is incorporated herein by reference for all purposes.

### BACKGROUND

Various example embodiments of the present inventive concepts relate to an image sensor, a system including the image sensor, and/or a method of manufacturing the image sensor, etc.

Image sensors are applied to devices within a variety of fields, such as devices for measuring a distance to a subject, creating a three-dimensional image, etc., beyond simply imaging a subject and creating a two-dimensional image. For example, in recent years, research into image sensors using single photon avalanche diodes (SPADs) has been actively undertaken to accurately and quickly measure the distance from the image sensor to a subject.

### SUMMARY

Various example embodiments provide an image sensor in which a first impurity region and a second impurity region may be effectively separated while improving dark current characteristics by disposing an element isolation film between the first and second impurity regions included in a single-photon avalanche diode disposed in a pixel of the image sensor, a system including the image sensor, and/or a method of manufacturing the image sensor, etc.

According to one or more example embodiments, an image sensor includes a substrate including a plurality of pixel areas, a pixel isolation film disposed in the substrate, the pixel isolation film separating the plurality of pixel areas from each other, and each pixel area of the plurality of pixel areas including, a first impurity region doped with an impurity of a first conductivity-type, a second impurity region around the first impurity region in a first direction parallel to an upper surface of the substrate, the second impurity region doped with an impurity of a second conductivity-type different from the first conductivity-type, and an element isolation film between the first impurity region and the second impurity region in the first direction, the element isolation film including, a first insulating layer in contact with the substrate, a second insulating layer on a first portion of the first insulating layer and formed of a material different from a material of the first insulating layer, and a third insulating layer, a first portion of the third insulating layer on the second insulating layer, and a second portion of the third insulating layer is directly in contact with the first insulating layer.

According to one or more example embodiments, an image sensor includes a substrate including a plurality of pixel areas, a pixel isolation film disposed in the substrate, the pixel isolation film separating the plurality of pixel areas from each other, each pixel area of the plurality of pixel areas including, a first impurity region doped with an impurity of a first conductivity-type, a second impurity region surrounding the first impurity region, the second impurity region doped with an impurity of a second conductivity-type different from the first conductivity-type, and an element isolation film between the first impurity region and the second impurity region, and the element isolation film has a first stack structure in a first direction different from a second stack structure of the element isolation film in a second direction, the first direction parallel to an upper surface of the substrate, and the second direction perpendicular to the upper surface of the substrate.

According to one or more example embodiments, an image sensor includes a substrate including a plurality of pixel areas, a pixel isolation film disposed in the substrate, the pixel isolation film separating the plurality of pixel areas from each other, and each pixel area of the plurality of pixel areas includes, a photodiode, a plurality of semiconductor elements, and an element isolation film between at least some of the plurality of semiconductor elements, the element isolation film including a first insulating layer, a second insulating layer, and a third insulating layer, the first insulating layer in contact with the substrate, the second insulating layer on the first insulating layer, the second insulating layer partially covering the first insulating layer, and the second insulating layer formed of a material different from a material of the first insulating layer, and a portion of third insulating layer on the second insulating layer.

### BRIEF DESCRIPTION OF DRAWINGS

The above and other aspects, features, and advantages of various example embodiments of the present inventive concepts will be more clearly understood from the following detailed description, taken in conjunction with the accompanying drawings, in which:

FIG. 1 is a schematic block diagram illustrating an image sensor according to one or more example embodiments;

FIG. 2 is a circuit diagram schematically illustrating pixels included in an image sensor according to one or more example embodiments;

FIG. 3 is a diagram illustrating an area of a pixel array included in an image sensor according to one or more example embodiments;

FIGS. 4A and 4B are cross-sectional views illustrating cross-sections taken along line I-I′ of FIG. 3 according to some example embodiments;

FIG. 5 is a plan view illustrating pixels included in an image sensor according to one or more example embodiments;

FIG. 6 is a cross-sectional view illustrating a section of a portion of FIG. 5 according to some example embodiments;

FIG. 7 is a plan view illustrating pixels included in an image sensor according to one or more example embodiments;

FIGS. 8 to 10 are cross-sectional views illustrating cross-sections of partial areas of FIG. 7 according to some example embodiments;

FIG. 11 is a diagram illustrating an area of a pixel array included in an image sensor according to one or more example embodiments;

FIGS. 12 to 17 are diagrams illustrating a method of manufacturing an image sensor according to one or more example embodiments;

FIG. 18 is a diagram illustrating a partial area of a pixel array included in an image sensor according to one or more example embodiments;

FIG. 19 is a diagram illustrating some pixels included in an image sensor according to one or more example embodiments; and

FIG. 20 is a diagram illustrating a semiconductor device according to one or more example embodiments.

### DETAILED DESCRIPTION

Hereinafter, various example embodiments will be described with reference to the accompanying drawings.

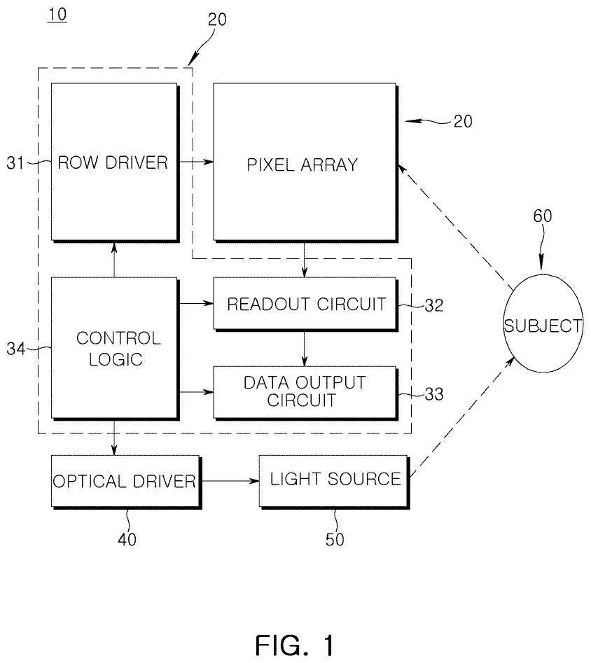

FIG. 1 is a simple block diagram of an image sensor according to one or more example embodiments.

Referring to FIG. 1, an image sensor 10 may include a pixel array 20, a peripheral circuit 30, an optical driver 40, a light source 50, and the like, but is not limited thereto, and for example may include a greater or lesser number of constituent components. The pixel array 20 may include a plurality of pixels disposed in an array in a plurality of rows and a plurality of columns. Each of the plurality of pixels may include at least one photoelectric conversion element generating electrical charge in response to light. The photoelectric conversion element may be a photodiode formed of a semiconductor material, and, for example, the photodiode may be a single-photon avalanche diode (SPAD), which may generate a photon avalanche effect.

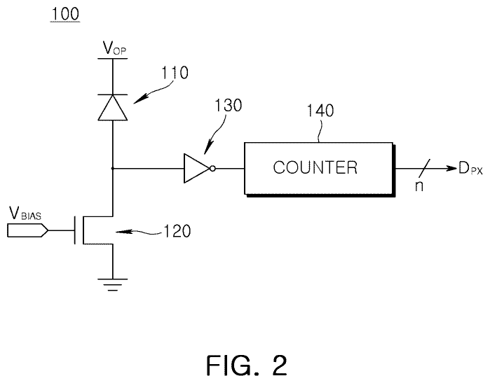

In addition to the photodiode, each of the plurality of pixels may further include a pixel circuit generating at least one pulse signal based on an electrical signal generated by a photon incident on the photodiode. In one or more example embodiments, the pixel circuit may include at least one transistor connected to at least one photodiode, a pulse generator, and/or a counter, etc. The configuration and operation of the pixel circuit will be described later with reference to FIG. 2.

The peripheral circuit 30 may include circuits for controlling the pixel array 20, but is not limited thereto. For example, the peripheral circuit 30 may include a row driver 31, a readout circuit 32, a data output circuit 33, control logic 34 (e.g., controller, control processing circuitry, etc.), and the like, but is not limited thereto. The row driver 31 may drive the pixel array 20 in units of row lines. For example, the row driver 31 may apply a control signal for applying a reverse bias voltage to a single-photon avalanche diode to each of the selected pixels arranged along the selected row line, but the example embodiments are not limited thereto.

The readout circuit 32 may be connected to pixels and column lines. The readout circuit 32 may read pixel signals through column lines from pixels connected to the row line selected by the row line selection signal of the row driver 31. In one or more example embodiments, the pixel signal may be at least one pulse signal generated by each pixel. The readout circuit 32 may convert the pixel signal into a digital pixel signal and may transmit the converted signal to the data output circuit 33. The data output circuit 33 outputs a digital pixel signal according to a desired and/or predetermined interface, and for example, the signal output by the data output circuit 33 may be transmitted to an image signal processor (ISP) connected to the image sensor 10, etc.

The control logic 34 may include a timing controller for controlling the operation timing of the row driver 31, the readout circuit 32, the data output circuit 33, and/or the like. Additionally, in one or more example embodiments, the control logic 34 may control the operation of the optical driver 40 that drives the light source 50, etc.

In one or more example embodiments, the optical driver 40 outputs an optical control signal in the form of a clock signal to the light source 50, and the light source 50 may irradiate light to a subject 60 in response to the light control signal. The light source 50 may include a laser diode, a light emitting diode, a near-infrared laser, a point light source, and/or the like, outputting light in a specific and/or desired wavelength band.

The light output from the light source 50 by the optical driver 40 may be reflected from the subject 60 and then reflected incident onto the pixel array 20. For example, one or more lenses may be disposed in a path where light reflected from the subject 60 is incident onto the pixel array 20. At least one of the plurality of pixels included in the pixel array 20 may generate a pixel signal in response to light reflected from the subject 60, etc.

The image sensor 10 according to one or more example embodiments illustrated in FIG. 1 may detect the distance to the subject 60 using a direct time-of-flight (ToF) method, but the example embodiments are not limited thereto. The direct ToF method may be a method of calculating the distance to the subject 60 by measuring and/or directly measuring the time from when light is irradiated to the subject 60 to when the light reflected from the subject 60 is incident in and/or received by the image sensor 10.

As described above, the pixel signal output from each of the plurality of pixels may be at least one pulse signal. The readout circuit 33 may calculate a time delay between a pixel signal output from each of the plurality of pixels and an optical control signal output from the optical driver 40 to the light source 50, and based thereon, may generate a digital pixel signal. For example, the readout circuit 33 may include a time-to-digital (TDC) circuit that converts time delay into a digital signal and/or distance information, etc. According to some example embodiments, one or more of the peripheral circuit 30, the row driver 31, the readout circuit 32, the data output circuit 33, the control logic 34, etc., may be implemented as processing circuitry. Processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

FIG. 2 is a circuit diagram illustrating pixels included in an image sensor according to one or more example embodiments.

Referring to FIG. 2, a pixel 100 included in an image sensor according to one or more example embodiments may include at least one photodiode 110, at least one transistor 120, at least one pulse generator 130, at least one counter 140, and the like, but the example embodiments are not limited thereto. The photodiode 110 may be a single photon avalanche diode as previously described, but is not limited thereto, and may output an electrical signal by generating an avalanche effect by photons incident from the outside (e.g., from an external source, etc.).

The transistor 120 may provide a quenching circuit that limits excess current (e.g., current above a threshold). For example, as the reverse voltage applied to the photodiode 110 increases, the probability that thermal electrons are in an excited state, and the tunneling probability increases, and therefore, a dark current flowing through the avalanche effect may be generated even when no photon is incident. Dark current may be added to the current generated by the avalanche effect due to photon incident resulting in excess current, and may stop the avalanche effect by turning on the transistor 120 to reduce the reverse voltage of the photodiode 110.

The pulse generator 130 may convert an electrical signal corresponding to the current flowing through the photodiode 110 into a pulse signal, and may include an inverter circuit, for example. An operating voltage Vop is applied to the cathode of the photodiode 110, and when the operating voltage Vop is greater than the breakdown voltage of the photodiode 110, the current generated by the avalanche effect may be input to the pulse generator 130.

The period of the pulse signal generated by the pulse generator 130 may vary depending on the surrounding illuminance (e.g., surrounding light levels, etc.). For example, the period of the pulse signal may be varied by an electrical signal generated from the photodiode 110 and a control signal determined according to and/or based on the ambient illuminance value. In one or more example embodiments, the period of the pulse signal may increase as ambient illuminance increases. For example, the pulse generator 130 may output a pulse signal determined as a logic level of ‘0’ or ‘1’ depending on whether the magnitude of the current generated in the diode 110 is greater than or equal to a desired threshold level.

The counter 140 may count the pulse signal and may output an n-bit digital pixel signal Dpx. According to at least one example embodiment, the counter 140 may be provided for each pixel or may be included in a readout circuit, but is not limited thereto.

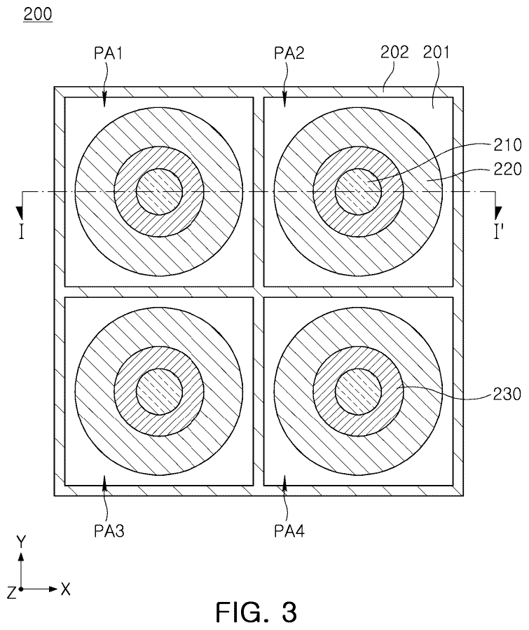

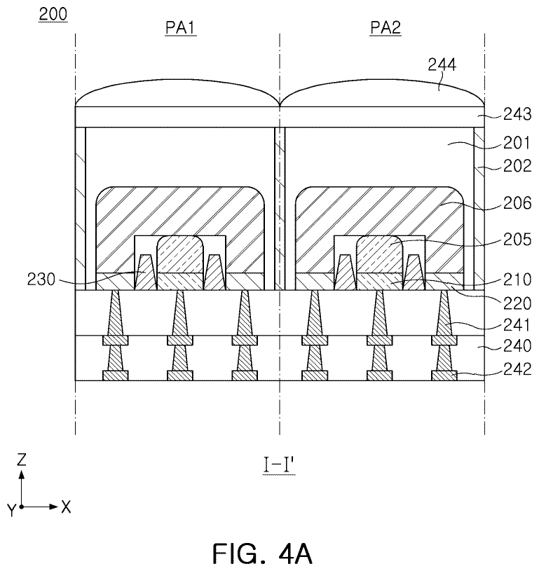

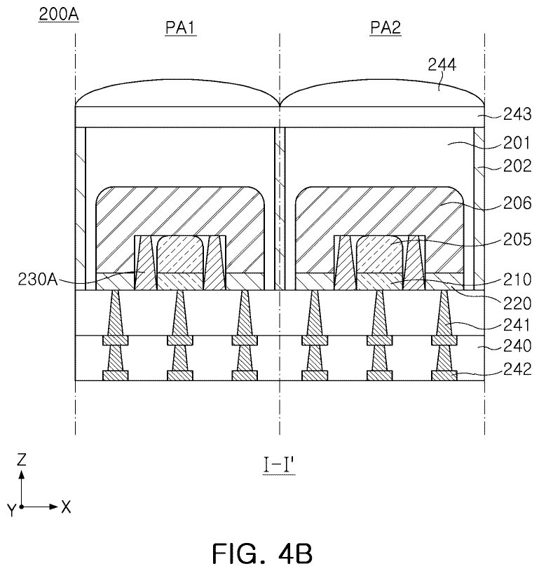

FIG. 3 is a diagram illustrating a portion of a pixel array included in an image sensor according to one or more example embodiments. FIGS. 4A and 4B are cross-sectional views illustrating a cross-section along the line I-I′ of FIG. 3 according to some example embodiments.

Referring to FIGS. 3 and 4A, a pixel array 200 of an image sensor according to one or more example embodiments may include a plurality of pixel areas PA1 to PA4, but is not limited thereto, and for example, may include a greater or lesser number of pixel areas, etc. The plurality of pixel areas PA1 to PA4 are divided and/or separated from each other by a pixel isolation film 202 formed in the substrate 201, and the pixel areas PA1 to PA4 may be arranged along directions parallel to the upper surface of the substrate 201.

A plurality of impurity regions, e.g., a first impurity region 210 and a second impurity region 220, etc., that provide photodiodes included in the pixel may be disposed in each of the plurality of pixel areas PA1 to PA4. The first impurity region 210 may be doped with an impurity of a first conductivity-type, and the second impurity region 220 may be doped with an impurity of a second conductivity-type different from the first conductivity-type, but the example embodiments are not limited thereto. In one or more example embodiments, the first impurity region 210 may be doped with a P-type impurity, and the second impurity region 220 may be doped with an N-type impurity, or vice versa. In this case, the first impurity region 210 may provide the anode of the photodiode, and the second impurity region 220 may provide the cathode of the photodiode.

An element isolation film 230 may be disposed between the first impurity region 210 and the second impurity region 220 in each of the plurality of pixel areas PA1 to PA4. The element isolation film 230 is formed of an insulating material and includes, for example, a plurality of insulating layers, and at least some of the plurality of insulating layers may be formed of different insulating materials. The element isolation film 230 is disposed between the first impurity region 210 and the second impurity region 220 in a first direction parallel to the upper surface of the substrate 201, and in at least one example embodiment illustrated in FIGS. 3 and 4, the first direction may be defined as a direction away from the center of the first impurity region 210, but is not limited thereto.

Referring to FIG. 4A, in the second direction (e.g., Z-axis direction) perpendicular to the upper surface of the substrate 201, well regions 205 and 206 may be formed below the first and second impurity regions 210 and 220, respectively. A first well region 205 doped with an impurity of a first conductivity-type is formed below the first impurity region 210, and a second well region 206 doped with an impurity of a second conductivity-type may be formed below the second impurity region 220, but the example embodiments are not limited thereto.

As illustrated in FIG. 4A, one surface of the first well region 205 may contact one surface of the second well region 206. In a reverse bias state in which a relatively low voltage is applied to the first impurity region 210 and a relatively high voltage is applied to the second impurity region 220, when a photon is incident (e.g., received) from the outside (e.g., an external source), a current due to an avalanche effect may flow at the contact surface of the first well region 205 and the second well region 206.

In the second direction, the first impurity region 210 may have a thickness smaller than the first well region 205, and the second impurity region 220 may have a thickness smaller than the second well region 206, but are not limited thereto. Additionally, in the second direction, the thickness of the element isolation film 230 may be greater than the thickness of each of the first and second impurity regions 210 and 220, but is not limited thereto. The thickness of the element isolation film 230 may be less than the sum of the thicknesses of the first impurity region 210 and the first well region 205, etc. Accordingly, as illustrated in FIG. 4, one surface of the element isolation film 230 buried in the substrate 201 may be separated from the second well region 206 in the second direction.

A plurality of contacts 241 may be connected to the first impurity region 210 and the second impurity region 220. For example, two or more contacts 241 may be connected to the second impurity region 220. The plurality of contacts 241 are disposed on the first surface of the substrate 201 and may be disposed within an interlayer insulating layer 240 along with the plurality of interconnection layers 242, but the example embodiments are not limited thereto.

The substrate 201 includes a second surface parallel to the first surface, and a planarization layer 243 and/or a plurality of micro lenses 244 may be disposed on the second surface, etc. For example, the number of the plurality of micro lenses 244 may be equal to the number of the plurality of pixel areas, e.g., pixel areas PA1 to PA4, etc., and one micro lens 244 may be disposed in each of the pixel areas PA1 to PA4, but the example embodiments are not limited thereto. Light reflected from the subject externally may be refracted by the micro lens 244 and enter the photodiode.

In one or more example embodiments, by disposing the element isolation film 230 between the first impurity region 210 and the second impurity region 220, insulating characteristics between the first impurity region 210 and the second impurity region 220 may be improved and/or increased. As a result, the breakdown voltage characteristics of the photodiode may be improved and/or increased by forming the element isolation film 230, and by significantly increasing the avalanche effect caused by incoming photons, the performance of the image sensor may be improved and/or increased.

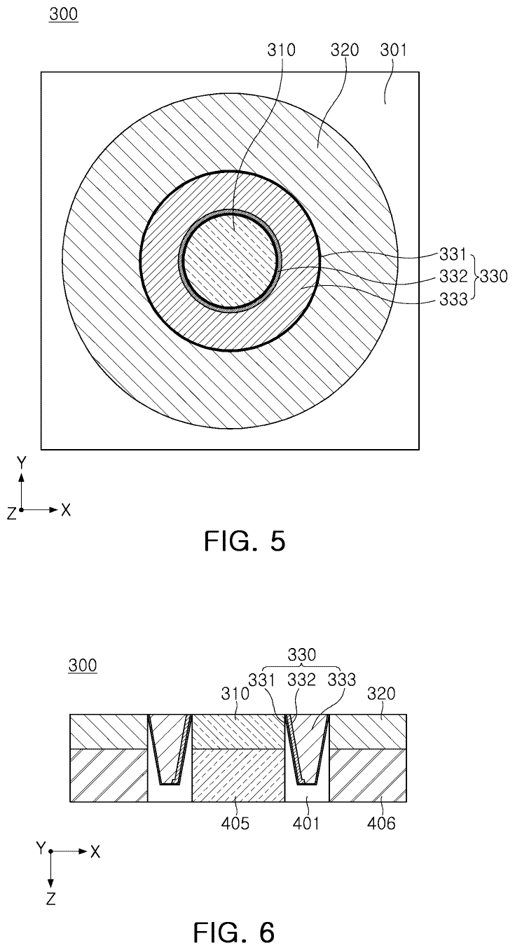

As previously described, the element isolation film 230 includes a plurality of insulating layers stacked on top of each other, and at least one of the plurality of insulating layers may be formed of an insulating material different from the other insulating layers to improve the dark current characteristics of the image sensor. For example, the element isolation film 230 includes a first insulating layer in direct contact with the substrate 201, and a second insulating layer stacked on the first insulating layer, and the first insulating layer may be formed of silicon oxide, and the second insulating layer may be formed of silicon nitride, but the example embodiments are not limited thereto, and other insulating materials may be used for either the first insulating layer and/or the second insulating layer. The element isolation film 230, first insulating layer, and second insulating layer will be discussed in greater detail in starting with FIG. 5, etc.

In one or more example embodiments, dark current characteristics in each of the plurality of pixels may be improved by the second insulating layer formed of silicon nitride having negative charge characteristics. However, like the first insulating layer, in the case in which the second insulating layer is formed on the entire surface of the first insulating layer (and/or covering the entire surface of the first insulating layer), the insulating properties between the first impurity region 210 and the second impurity region 220 may be weakened and/or decreased by the second insulating layer. Therefore, the breakdown voltage characteristics of the diode may deteriorate and/or decrease, and the performance of the image sensor may deteriorate and/or decrease. On the other hand, if the second insulating layer is omitted and the element isolation film 230 is formed only of silicon oxide (and/or multiple layers of silicon oxide, etc.), the dark current characteristics of the image sensor may also deteriorate and/or decrease.

Accordingly, in one or more example embodiments of the present inventive concepts, the second insulating layer included in the element isolation film 230 and formed of silicon nitride may be formed only in some areas. For example, the second insulating layer may be formed only in a portion of the region close to the first impurity region 210, or may be formed to include a plurality of regions separated from each other. Accordingly, the performance of the image sensor may be improved by improving the dark current characteristics and significantly reducing the weakening of the insulation characteristics of the first and second impurity regions 210 and 220, etc.

In at least one example embodiment illustrated in FIG. 4B, one surface of the element isolation film 230A buried in the substrate 201 in each of the pixel areas PA1 to PA4 of the image sensor 200A may contact the second well region 206, but the example embodiments are not limited thereto. As illustrated in FIG. 4B, the thickness of the element isolation film 230A may be equal to and/or substantially equal to (within +/−10% of) the sum of the thicknesses of the first impurity region 210 and the first well region 205, and accordingly, one surface of the element isolation film 230A buried in the substrate 201 may contact the second well region 206.

FIG. 5 is a plan view illustrating a pixel included in an image sensor according to one or more example embodiments. FIG. 6 is a cross-sectional view illustrating a cross-section of a portion of FIG. 5.

Referring to FIGS. 5 and 6, at least one pixel 300 of an image sensor according to one or more example embodiments may include a plurality of impurity regions, such as a first impurity region 310, a second impurity region 320, etc., and/or an element isolation film 330, etc., formed on a substrate 301, but is not limited thereto. The pixel 300 is divided and/or separated from other adjacent pixels by a pixel isolation film, and the first impurity region 310 and the second impurity region 320 may be separated from each other by the element isolation film 330.

The first impurity region 310 and the second impurity region 320 are doped with impurities of different conductivity-types, and a photodiode may be provided by the first impurity region 310 and the second impurity region 320, etc. For example, the first impurity region 310 may be doped with a P-type impurity to provide an anode of a photodiode, and the second impurity region 320 may be doped with an N-type impurity to provide a cathode of a photodiode, or vice versa.

In order for a current to flow due to the avalanche effect in the photodiode producing and/or causing photons to flow into the pixel 300, a reverse bias voltage should be applied to the first impurity region 310 and the second impurity region 320, and it is desired and/or necessary to secure the insulating properties of the first impurity region 310 and the second impurity region 320. In one or more example embodiments, by disposing the element isolation film 330 between the first impurity region 310 and the second impurity region 320, insulation characteristics between the first impurity region 310 and the second impurity region 320 may be improved and/or secured.

On the other hand, a first well region 305 doped with P-type impurities (e.g., the same type of impurities as the first impurity region 310) is formed below the first impurity region 310, and a second well region 306 doped with N-type impurities (e.g., the same type of impurities as the second impurity region 320) may be formed below the second impurity region 320. The doping concentration of the first impurity region 310 is higher than the doping concentration of the first well region 305, and the doping concentration of the second impurity region 320 may be higher than the doping concentration of the second well region 306. Additionally, a portion of the second well region 306 may contact a portion of the first well region 305 within the substrate 301.

Referring to FIGS. 5 and 6, the element isolation film 330 may include a first insulating layer 331, a second insulating layer 332, and/or a third insulating layer 333, etc., but is not limited thereto. The first insulating layer 331 may directly contact the substrate 301 and may also contact the first impurity region 310 and the second impurity region 320.

In one or more example embodiments, the first insulating layer 331 may be formed by oxidizing the surface of the substrate 301 exposed externally within a trench formed by removing a portion of the substrate 301 in a shape corresponding to the element isolation film 330, but the example embodiments are not limited thereto. In this manner, by forming the first insulating layer 331 by oxidizing the externally exposed surface of the substrate 301, damage incurred during the process of forming a trench by removing a portion of the substrate 301 may be cured, repaired, and/or decreased. When the substrate 301 is a silicon substrate, the first insulating layer 331 may include silicon oxide, but is not limited thereto and may be a different insulating material.

The second insulating layer 332 is formed on the first insulating layer 331 by a deposition process or the like, and may be formed only in a partial area of the first insulating layer 331 exposed externally. In at least one example embodiment illustrated in FIGS. 5 and 6, the second insulating layer 332 may be formed only on a portion of the surface of the first insulating layer 331, adjacent to the first impurity region 310, and may not be formed on the remaining surface adjacent to the second impurity region 320, but the example embodiments are not limited thereto.

Accordingly, the second insulating layer 332 may include a first side region adjacent to the first impurity region 310 between the first impurity region 310 and the second impurity region 320. Also, in one or more example embodiments, as illustrated in FIGS. 5 and 6, the second insulating layer 332 may further include a lower region formed on the lower surface of the first insulating layer 331, but is not limited thereto.

Since the second insulating layer 332 includes the first side region, a portion (e.g., a subset) of the element isolation film 330 may have a stack structure in which the first insulating layer 331, the second insulating layer 332, and the third insulating layer 333, etc., are arranged in that order, in a first direction parallel to the upper surface of the substrate 301, but the example embodiments are not limited thereto. On the other hand, in the second direction perpendicular to the upper surface of the substrate 301, a portion (e.g., a subset) of the element isolation film 330 may have a stack structure in which the first insulating layer 331 and the third insulating layer 333 are disposed in order (e.g., at least a portion of the first insulating layer 331 and at least a portion of the third insulating layer 333 are directly connected, etc.), but is not limited thereto.

The third insulating layer 333 is formed on the first insulating layer 331 and the second insulating layer 332, and accordingly, the second insulating layer 332 may be disposed between the first insulating layer 331 and the third insulating layer 333, etc. The second insulating layer 332 is formed of a material different from a material of the first insulating layer 331, for example, formed of silicon nitride, and the third insulating layer 333 may be formed of the same material as a material of the first insulating layer 331, for example, silicon oxide, but the example embodiments are not limited thereto. In a position in which the lower region and the first side region are not formed, in detail, in a position in which the second insulating layer 332 is not formed, a portion of the first insulating layer 331 may be in direct contact with the third insulating layer 333.

By forming the second insulating layer 332 with negative charge characteristics, dark current that may occur in the pixel 300 may be effectively reduced and/or suppressed. Additionally, in one or more example embodiments, the second insulating layer 332 is formed only on a portion (e.g., subset) of the surface of the first insulating layer 331, and thus deterioration in insulation characteristics between the first impurity region 310 and the second impurity region 320 may be significantly reduced and the breakdown voltage characteristics of the photodiode may be improved.

For example, in a case in which the second insulating layer 332 is formed entirely on the surface of the first insulating layer 331, a charge transfer path between the first impurity region 310 and the second impurity region 320 may be provided by the second insulating layer 332. In this case, the breakdown voltage characteristics of the photodiode may change and the performance of the image sensor including the pixel 300 may deteriorate and/or decrease. On the other hand, if the element isolation film 330 is formed using only a single material, e.g., silicon oxide, without the second insulating layer 332, or if the element isolation film 330 is not formed, the dark current characteristics of the pixel 300 may be deteriorated and/or decreased.

In one or more example embodiments of the present inventive concepts, to improve and/or ensure insulation characteristics between the first impurity region 310 and the second impurity region 320 while decreasing and/or suppressing dark current, the second insulating layer 332 may be formed only on a portion (e.g., a subset) of the surface of the first insulating layer 331 in the element isolation film 330. Therefore, a photodiode that may effectively generate an avalanche effect due to photons may be implemented in the pixel 300, and the noise characteristics of the image sensor may be improved by reducing dark current.

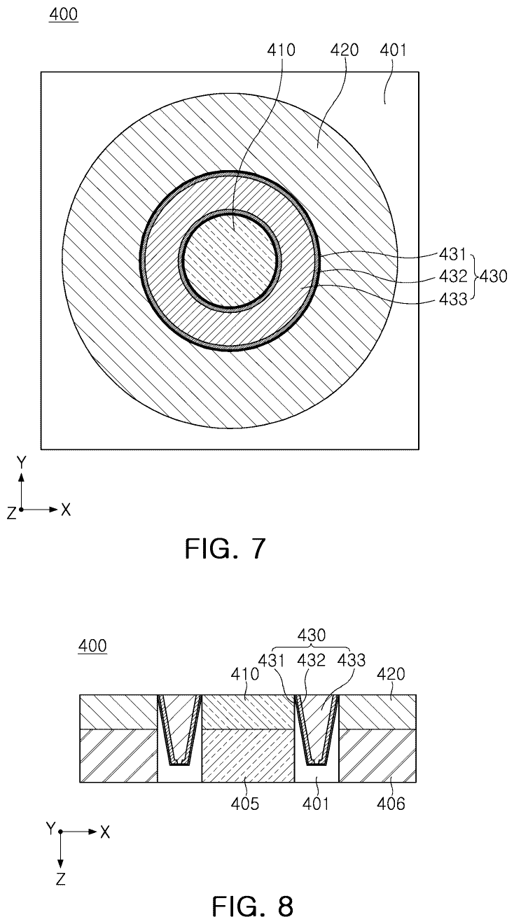

FIG. 7 is a plan view illustrating a pixel included in an image sensor according to one or more example embodiments. FIGS. 8 to 10 are cross-sectional views illustrating a cross-section of a partial area of FIG. 7 according to some example embodiments.

Referring first to FIGS. 7 and 8, a pixel 400 of an image sensor according to one or more example embodiments may include a plurality of impurity regions, such as a first impurity region 410, a second impurity region 420, etc., and/or an element isolation film 430 formed in the substrate 401, but is not limited thereto. The pixel 400 is divided and/or separated from other adjacent pixels by a pixel isolation film, and the first impurity region 410 and the second impurity region 420 may be separated from each other by the element isolation film 430, etc.

The first impurity region 410 and the second impurity region 420 may be formed similarly to the example embodiments previously described with reference to FIGS. 5 and 6, but is not limited thereto. The second impurity region 420 is formed to surround the first impurity region 410 in a direction parallel to the upper surface of the substrate 401, the first impurity region 410 is doped with an impurity of a first conductivity-type, and the second impurity region 420 may be doped with an impurity of a second conductivity-type. A first well region 405 doped with an impurity of a first conductivity-type is formed below the first impurity region 410, and a second well region 406 doped with an impurity of a second conductivity-type may be formed below the second impurity region 420. Each of the first impurity region 410 and the second impurity region 420 may have a shape other than a circular shape depending on one or more example embodiments.

Referring to FIGS. 7 and 8, the element isolation film 430 may include a first insulating layer 431, a second insulating layer 432, a third insulating layer 433, and the like, but is not limited thereto. The first insulating layer 431 and the third insulating layer 433 are formed of the same material, for example, silicon oxide, and the second insulating layer 432 may be formed of a material different from a material of the first insulating layer 431 and the third insulating layer 433, for example, the second insulating layer 432 may be formed of silicon nitride, etc., but the example embodiments are not limited thereto.

However, unlike the example embodiments described with reference to FIGS. 5 and 6, in the example embodiments illustrated in FIGS. 7 and 8, the second insulating layer 432 may include a first side region adjacent to the first impurity region 410 and a second side region adjacent to the second impurity region 420, etc. The first side region and the second side region may be separated from each other on the lower surface of the first insulating layer 431.

In this manner, by forming the second insulating layer 432 to have a plurality of regions separated from each other between the first insulating layer 431 and the third insulating layer 433, dark current that may occur in the pixel 400 may be reduced and/or suppressed, and simultaneously, the insulating properties of the first and second impurity regions 410 and 420 may be improved and/or secured. Therefore, when a photon is incident on the photodiode in a reverse bias state in which a relatively low voltage is applied to the first impurity region 410 and a relatively high voltage is applied to the second impurity region 420, current may be generated by the avalanche effect.

In at least one example embodiment illustrated in FIG. 8, the second insulating layer 432 may further include a lower region formed on the lower surface of the first insulating layer 431, in addition to the first side region adjacent to the first impurity region 410 and the second side region adjacent to the second impurity region 420, but is not limited thereto. In an example, the lower region may extend from the first side region and/or the second side region, etc. Therefore, in a location in which the lower region is not formed, the first insulating layer 431 may directly contact the third insulating layer 433. In other words, the second insulating layer 432 may be in direct contact with a first portion of the first insulating layer 431, a first portion of the third insulating layer 433 may be in direct contact with a second portion of the first insulating layer 431, and a second portion of the third insulating layer 433 may be in direct contact with at least a portion of the second insulating layer 432.

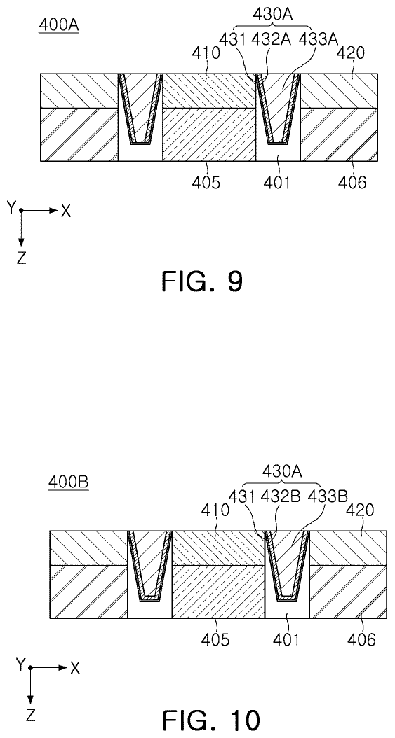

On the other hand, in a pixel 400A according to at least one example embodiment illustrated in FIG. 9, a second insulating layer 432A may not include a lower region formed on the lower surface of the first insulating layer 431. In detail, the second insulating layer 432A may include only side regions formed along the sidewall of the first insulating layer 431. Accordingly, a first insulating layer 431 and a third insulating layer 433A of the element isolation film 430A may directly contact each other in a location where the second insulating layer 432A is not formed.

Since the second insulating layer 432A includes a first side region adjacent to the first impurity region 410 and a second side region adjacent to the second impurity region 420, in a first direction parallel to the upper surface of the substrate 401, the element isolation film 430A may have a stack structure (e.g., a first stack structure, etc.) in which the first insulating layer 431, the second insulating layer 432A, and the third insulating layer 433A are disposed in that order, but not limited thereto. On the other hand, in the second direction perpendicular to the upper surface of the substrate 401, the element isolation film 430A may have a stack structure (e.g., second stack structure) in which the first insulating layer 431 and the third insulating layer 433A are disposed in that order, but not limited thereto. The element isolation film 430A may have a different stack structures in the first direction and the second direction, etc.

In a pixel 400B according to at least one example embodiment illustrated in FIG. 10, a second insulating layer 432B may be formed to cover the entire surface of a first insulating layer 431, but the example embodiments are not limited thereto. Since the second insulating layer 432B covers the entire surface of the first insulating layer 431, the first insulating layer 431 and the third insulating layer 433B may not be in direct contact with each other. As illustrated in FIG. 10, by forming the second insulating layer 432B on the entire surface of the first insulating layer 431, dark current characteristics may be effectively improved using the element isolation film 430B.

As in the various example embodiments illustrated in FIGS. 8 to 10, the element isolation films 430, 430A, and/or 430B, etc., may be formed into various structures in consideration of the characteristics of the image sensor. If it is desired and/or necessary to properly improve and/or balance both dark current characteristics and the insulation characteristics between the impurity regions 410 and 420, as in the example embodiments illustrated in FIGS. 8 and 9, the element isolation films 430 and 430A may be formed in a structure in which at least a portion of the first insulating layer 431 is in direct contact with the third insulating layer 433 and 433A, but the example embodiments are not limited thereto. On the other hand, when improving dark current characteristics is most important and/or more desired, the second insulating layer 432B may be formed to have a structure that covers the entire surface of the first insulating layer 431, as in the example embodiment illustrated in FIG. 10.

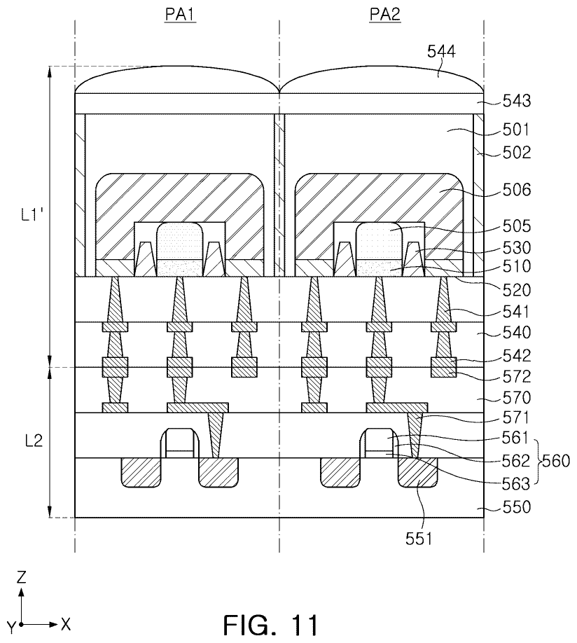

FIG. 11 is a diagram illustrating some pixels included in an image sensor according to one or more example embodiments.

Referring to FIG. 11, an image sensor 500 according to one or more example embodiments includes a plurality of pixel areas, such as pixel areas PA1 and PA2, etc., divided by a pixel isolation film 502, and at least one pixel may be formed in each of the plurality of pixel areas PA1 and PA2, etc. Each of the pixels included in the image sensor 500 according to one or more example embodiments may include a photodiode that outputs an electrical signal in response to light, and a pixel circuit that converts the current of the photodiode into a pulse signal and limits the excess current of the photodiode, etc. As previously described with reference to FIG. 2, the pixel circuit may include a quenching circuit that limits the excess current of the photodiode, a pulse generator that converts the current of the photodiode into a pulse signal, a counter, and the like.

In one or more example embodiments, semiconductor elements providing the quenching circuit, the pulse generator, the counter, and the like, may be formed on a separate substrate from the photodiode, but is not limited thereto. Referring to FIG. 11, the image sensor 500 includes a plurality of layers, e.g., a first layer L1 and a second layer L2, etc., and the first layer L1 and the second layer L2 may be bonded to each other using Cu—Cu bonding, but the example embodiments are not limited thereto.

Referring to the first layer L1, in the first substrate 501, a pixel isolation film 502, a first impurity region 510 and a second impurity region 520 that provide at least one photodiode, an element isolation film 530 separating the first impurity region 510 from the second impurity region 520, and the like, may be formed. The element isolation film 530 includes a plurality of insulating layers, e.g., first to third insulating layers, etc., sequentially stacked from the first substrate 501, and the second insulating layer may be formed of a material different from a material of the first and third insulating layers, but the example embodiments are not limited thereto. Additionally, the first and third insulating layers may be in direct contact at least in some areas with each other.

A plurality of contacts 541 connected to the first and second impurity regions 510 and 520 are disposed on the first surface of the first substrate 501, and the plurality of contacts 541 may be disposed in the first interlayer insulating layer 540 together with a plurality of interconnection layers 542. On the other hand, a planarization layer 543 and/or a plurality of micro lenses 544 may be disposed on the second surface of the substrate 501 parallel to the first surface.

Next, referring to the second layer L2, a plurality of semiconductor elements may be formed on a second substrate 550. Each of the plurality of semiconductor elements includes a gate structure 560 and an active region 551, etc., and the gate structure 560 may include a gate electrode layer 561, a gate spacer 562, and/or a gate insulating layer 563, etc. The plurality of semiconductor elements may provide quenching circuits, pulse generators, counters, and the like.

An element isolation film may also be formed in the second substrate 550, and the element isolation film formed in the second substrate 550 may electrically isolate at least portions of the active regions 551 from each other. Depending on one or more example embodiments, the element isolation film formed in the second substrate 550 may have a similar or identical structure to the element isolation film 530 formed in the first substrate 501, but the example embodiments are not limited thereto. For example, the element isolation film formed in the second substrate 550 may include a first insulating layer in direct contact with the second substrate 550, a second insulating layer and a third insulating layer sequentially stacked on the first insulating layer, but is not limited thereto, and for example, may include a greater or lesser number of insulating layers, etc. The second insulating layer covers only a partial area of the first insulating layer, and the partial area of the first insulating layer may be in direct contact with a partial area of the third insulating layer, but the example embodiments are not limited thereto. The second insulating layer may be formed of a material different from a material of the first insulating layer and the third insulating layer, but is not limited thereto.

A plurality of semiconductor elements included in the second layer L2 are connected to a plurality of contacts 571 and a plurality of interconnection layers 572 formed on the second substrate 550, and the plurality of contacts 571 and the plurality of interconnection layers 572 may be disposed in a second interlayer insulating layer 570. Some of the plurality of interconnection layers 572 are exposed externally to provide second pads, and may be bonded to the first pads provided as some of the plurality of interconnection layers 542 included in the first layer L1 are exposed externally, by using, for example, a Cu—Cu bonding method, etc.

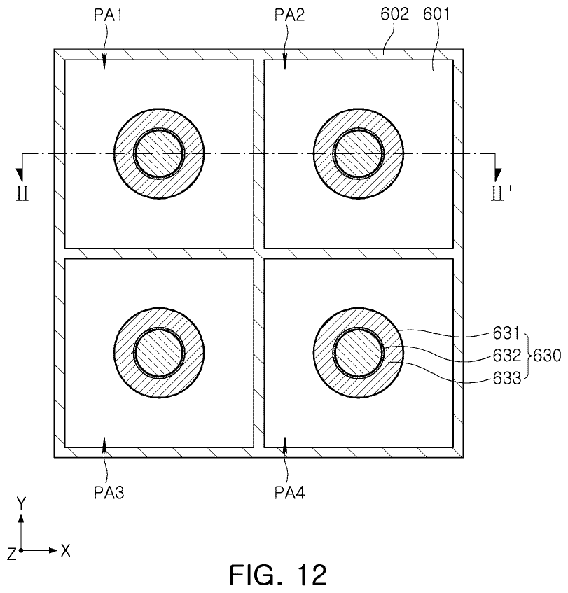

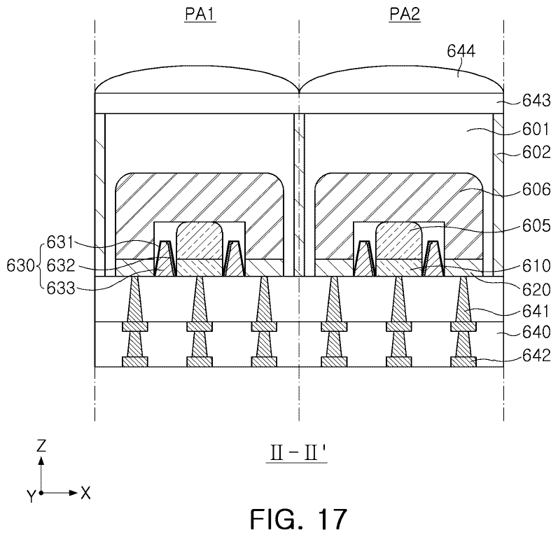

FIGS. 12 to 17 are drawings illustrating a method of manufacturing an image sensor according to one or more example embodiments.

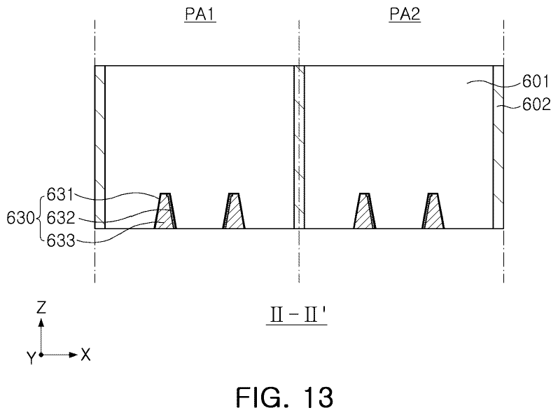

First, referring to FIGS. 12 and 13, a pixel isolation film 602 is formed in a substrate 601, and a plurality of pixel areas, such as pixel areas PA1 to PA4, etc., may be defined by the pixel isolation film 602. An element isolation film 630 is formed in each of the plurality of pixel areas PA1 to PA4, and the element isolation film 630 may include a first insulating layer 631, a second insulating layer 632, and/or a third insulating layer 633, etc.

To form the element isolation film 630, a trench is formed in the substrate 601 to a desired and/or predetermined depth, and the surface of the substrate 601 exposed within the trench may be oxidized to first form the first insulating layer 631. Therefore, the first insulating layer 631 may include, e.g., silicon oxide, and damage occurring in the substrate 601 by forming the trench may be cured, repaired, and/or decreased in the process of forming the first insulating layer 631, but the example embodiments are not limited thereto.

Once the first insulating layer 631 is formed, for example, a silicon nitride layer may be deposited thereon, but is not limited thereto. The silicon nitride layer may be formed conformally along the surface of the first insulating layer 631 to have a shape corresponding to the first insulating layer 631. Thereafter, the second insulating layer 632 may be formed by selectively removing at least a portion of the silicon nitride layer.

In at least one example embodiment illustrated in FIGS. 12 and 13, a portion (e.g., subset) of the silicon nitride layer may be removed in a location close to the element isolation film 602. Accordingly, the second insulating layer 632 may be formed along the inner wall of the element isolation film 630. Thereafter, the third insulating layer 633 may be formed by filling the remaining space inside the trench with an insulating material, such as silicon oxide, etc. A portion of the third insulating layer 633 may be in direct contact with the first insulating layer 631, and the remaining area may be in direct contact with the second insulating layer 632.

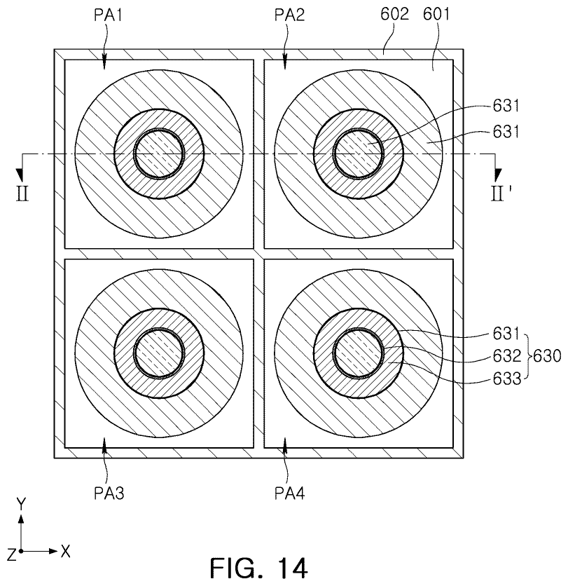

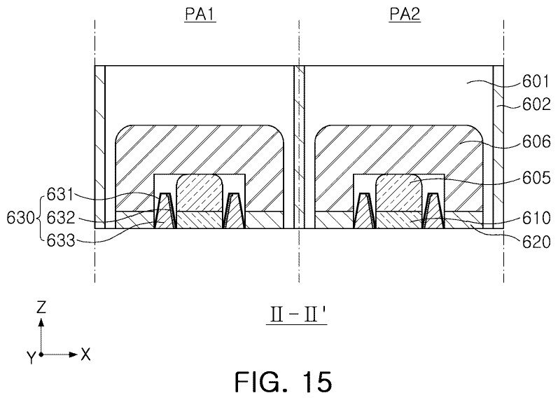

Referring to FIGS. 14 and 15, according to some example embodiments, a first impurity region 610 and a second impurity region 620 may be formed on an inner side and an outer side of the element isolation film 630, respectively. First, before forming the first impurity region 610 and the second impurity region 620, a first well region 605 and a second well region 606 may be formed by an ion implantation process, but the example embodiments are not limited thereto. The first well region 605 is doped with a P-type impurity, and the second well region 606 is doped with an N-type impurity, and as illustrated in FIG. 14, the first well region 605 and the second well region 606 may contact each other within the substrate 601, but are not limited thereto.

The first impurity region 610 is formed by a process of additionally injecting P-type impurities into the first well region 605, and accordingly, the first impurity region 610 may have a higher doping concentration than the first well region 605. The second impurity region 620 is formed by a process of additionally injecting N-type impurities into the second well region 606, and accordingly, the second impurity region 620 may have a higher doping concentration than the second well region 606. As illustrated in FIG. 14, the depth of each of the first and second impurity regions 610 and 620 may be shallower than the depth of the element isolation film 630.

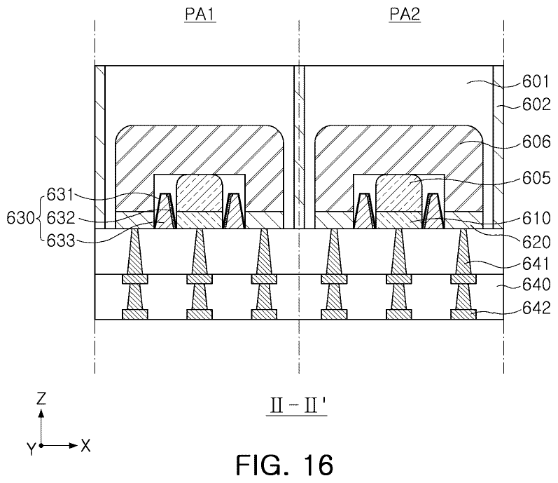

Next, referring to FIG. 16, a plurality of contacts 641, a plurality of interconnection layers 642, and/or an interlayer insulating layer 640, etc., may be formed on the first surface of the substrate 601. Thereafter, as illustrated in FIG. 16, a planarization layer 643 and a plurality of micro lenses 644 may be formed on the second surface of the substrate 601. If desired and/or necessary, a Chemical Mechanical Polishing (CMP) process to remove a partial area of the substrate 601 may be performed prior to forming the planarization layer 643 and the plurality of micro lenses 644, but the example embodiments are not limited thereto.

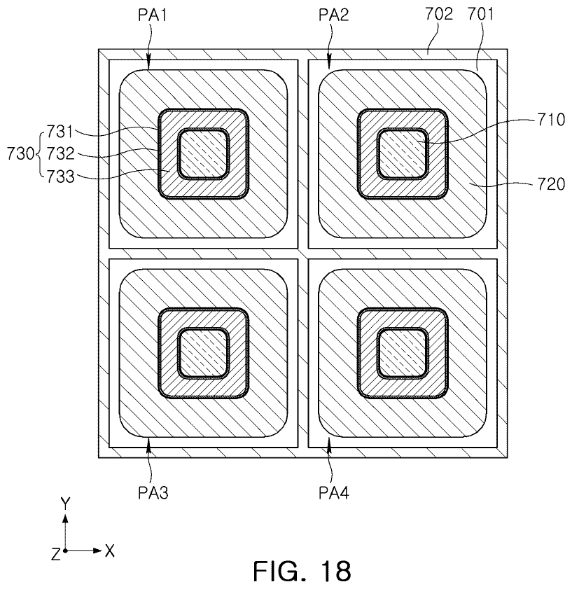

FIG. 18 is a diagram illustrating some pixels included in an image sensor according to one or more example embodiments.

Referring to FIG. 18, a pixel array 700 of an image sensor according to one or more example embodiments may include a plurality of pixel areas, such as PA1 to PA4, but is not limited thereto. The plurality of pixel areas PA1 to PA4 may be divided and/or separated from each other by a pixel isolation film 702 formed in the substrate 701.

A first impurity region 710, a second impurity region 720, and/or an element isolation film 730 that provide a photodiode included in the pixel may be formed in each of the plurality of pixel areas PA1 to PA4, etc. In at least one example embodiment illustrated in FIG. 18, each of the first impurity region 710, the second impurity region 720, and the element isolation film 730 may have a shape closer to a quadrangular shape than a circle, but the example embodiments are not limited thereto, and for example, may have other shapes besides quadrangular or circular shapes.

As described above, the element isolation film 730 may include a plurality of insulating layers, such as first to third insulating layers 731-733, but is not limited thereto. The first insulating layer 731 may be in direct contact with the substrate 701, and the second insulating layer 732 may be disposed between the first insulating layer 731 and the third insulating layer 733, etc. The second insulating layer 732 is formed to cover only a portion of the surface of the first insulating layer 731, and therefore, a partial area of the third insulating layer 733 may be in direct contact with the first insulating layer 731, etc. In this manner, by forming the second insulating layer 732 to cover only a portion (e.g., a subset) of the surface of the first insulating layer 731, both the dark current characteristics of the image sensor and the breakdown voltage characteristics of the photodiode may be improved.

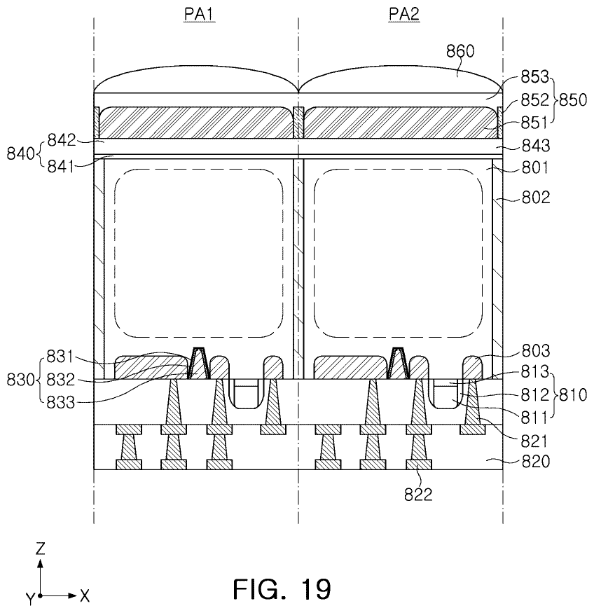

FIG. 19 is a diagram illustrating some pixels included in an image sensor according to one or more example embodiments.

An image sensor including a pixel array 800 according to at least one example embodiment illustrated in FIG. 19 may be a device generating an image using at least one pixel signal corresponding to electrical charges generated in a photodiode PD. Unlike other example embodiments described above, the photodiode PD of FIG. 19 may not use the avalanche effect.

A plurality of pixel areas, such as PA1 and PA2, etc., may be defined by a pixel isolation film 802 formed in a substrate 801. The pixel isolation film 802 is formed to penetrate the substrate 801, and the photodiode PD may be formed in the substrate 801 in each of the plurality of pixel areas PA1 and PA2, etc.

An active region 803 and a gate structure 810 are disposed on the first surface of the substrate 801, and the active region 803 and the gate structure 810 may provide a plurality of semiconductor elements included in the pixel circuit, but the example embodiments are not limited thereto. The gate structure 810 may include a gate electrode layer 811, a gate spacer 812, and/or a gate insulating layer 813, etc. A plurality of contacts 821 and a plurality of interconnection layers 822 are connected to the plurality of active regions 803 and the gate structure 810, and the plurality of contacts 821 and the plurality of interconnection layers 822 may be disposed within the interlayer insulating layer 820, but are not limited thereto.

On the other hand, a planarization layer 840, a color filter layer 850, and/or a plurality of micro lenses 860, etc., may be disposed in order on the second surface of the substrate 801, but are not limited thereto. The planarization layer 840 includes, e.g., a first planarization layer 841 and a second planarization layer 842, etc., and for example, the first planarization layer 841 may be in contact with the substrate 801 and may be formed of a material having a higher dielectric constant than the second planarization layer 842, but the example embodiments are not limited thereto. The first planarization layer 841 may have a thickness smaller than a thickness of the second planarization layer 842, and some of the defects of the substrate 801 may be cured, repaired, and/or decreased by the first planarization layer 841, but the example embodiments are not limited thereto.

The color filter layer 850 may include a color filter 851, a filter isolation film 852, a horizontal insulating layer 853, and the like. The filter isolation film 852 is formed in a position corresponding to the pixel isolation film 803, and accordingly, the color filter 851 may be arranged along the plurality of pixel areas PA1 and PA2, etc. The horizontal insulating layer 853 may be disposed on the color filter 851, and the micro lenses 860 may be disposed on the horizontal insulating layer 853. The micro lens 860 refracts light incident from the outside (e.g., an external source) and advances the light to the color filter 851, and light in a specific and/or desired wavelength band may be selectively incident on the photodiode PD by the color filter 851.

Referring to FIG. 19, an element isolation film 830 for electrical separation may be disposed between at least some of the plurality of semiconductor elements. The element isolation film 830 may include a plurality of insulating layers, such as a first insulating layer 831, a second insulating layer 832, and/or a third insulating layer 833, etc., that are sequentially stacked. In detail, the first insulating layer 831 may be in direct contact with the substrate.

The element isolation film 830 may have a structure similar to the element isolation film disposed between the first and second impurity regions that provide a photodiode in one or more of the previously described example embodiments. For example, the second insulating layer 832 is formed in the element isolation film 830 to cover only a portion of the surface of the first insulating layer 831, and therefore, a portion of the third insulating layer 833 may directly contact the first insulating layer 831.

Unlike the first insulating layer 831 and the third insulating layer 833, the second insulating layer 832 is formed of silicon nitride, and therefore dark current generated when there is no light coming from the outside (and/or external source) may be reduced and/or prevented. However, if the second insulating layer 832 is formed in the element isolation film 830 to cover the entire surface of the first insulating layer 831, the performance of the image sensor may deteriorate due to weakened insulation characteristics between the active regions 803 adjacent to both sides of the element isolation film 830. To reduce and/or prevent such problems from occurring, in one or more example embodiments of the present inventive concepts, the second insulating layer 832 is formed to cover only a portion (e.g., subset) of the surface of the first insulating layer 831, so that in addition to dark current characteristics, insulation characteristics between the active regions 803 may be improved and/or secured.

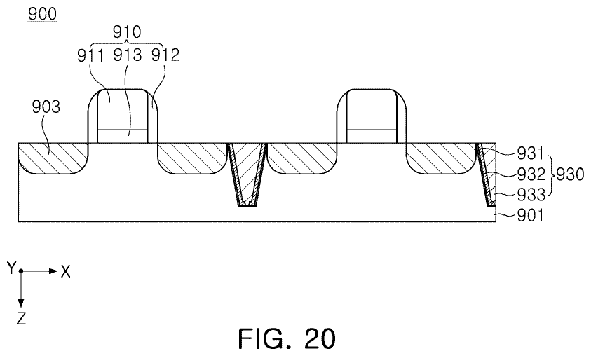

FIG. 20 is a diagram illustrating a semiconductor device according to one or more example embodiments.

As illustrated in FIG. 20, an element isolation film applied to an image sensor according to various example embodiments may also be disposed between active regions 903 formed in the substrate 901 in a semiconductor device 900. The respective active regions 903 may provide a semiconductor element such as a transistor, etc., together with a gate structure 910, and may be a region doped with impurities injected into the substrate 901. The gate structure 910 may include a gate electrode layer 911, a gate spacer 912, a gate insulating layer 913, and the like.

Referring to FIG. 20, the element isolation film 930 may include a first insulating layer 931, a second insulating layer 932, a third insulating layer 933, and the like. In at least one example embodiment illustrated in FIG. 20, the second insulating layer 932 of the element isolation film 930 may cover only a portion of the first insulating layer 931, and accordingly, at least a portion of the first insulating layer 931 may be in direct contact with the third insulating layer 933. However, the structure of the element isolation film 930 is not necessarily limited to this form, and as another example, the second insulating layer 932 may be formed to cover the entire surface of the first insulating layer 931.

As set forth above, according to one or more example embodiments, at least one pixel of an image sensor may include a first impurity region and a second impurity region providing a single-photon avalanche diode, and an element isolation film may be disposed between the first impurity region and the second impurity region. The element isolation film has a structure in which a plurality of insulating layers are sequentially stacked, and at least one insulating layer among the plurality of insulating layers may be formed only on a portion of a lower insulating layer rather than on the entire surface of the lower insulating layer. Therefore, charge movement between the first impurity region and the second impurity region may be reduced and/or prevented and the photon avalanche effect may be significantly increased, and dark current that may occur in the pixels of the image sensor may consequently be reduced and/or suppressed.

While various example embodiments have been illustrated and described above, it will be apparent to those of ordinary skill in the art that modifications and variations could be made to the example embodiments without departing from the scope of the present inventive concepts as defined by the appended claims.

What is claimed is:

1. An image sensor comprising:
a substrate including a plurality of pixel areas;
a pixel isolation film disposed in the substrate, the pixel isolation film separating the plurality of pixel areas from each other; and
each pixel area of the plurality of pixel areas including,
a first impurity region doped with an impurity of a first conductivity-type,
a second impurity region around the first impurity region in a first direction parallel to an upper surface of the substrate, the second impurity region doped with an impurity of a second conductivity-type different from the first conductivity-type, and
an element isolation film between the first impurity region and the second impurity region in the first direction, the element isolation film including,
a first insulating layer in contact with the substrate,
a second insulating layer on a first portion of the first insulating layer and formed of a material different from a material of the first insulating layer, and
a third insulating layer, a first portion of the third insulating layer on the second insulating layer, and a second portion of the third insulating layer is directly in contact with the first insulating layer.

2. The image sensor of claim 1, wherein the second insulating layer includes a first side region between the first insulating layer and the third insulating layer in the first direction and adjacent to the first impurity region.

3. The image sensor of claim 2, wherein
the second insulating layer further includes a second side region between the first insulating layer and the third insulating layer in the first direction and adjacent to the second impurity region; and
the second portion of the third insulating layer is between the first side region and the second side region.

4. The image sensor of claim 2, wherein the second insulating layer further includes:
a lower region between the first insulating layer and the third insulating layer in a second direction, the lower region extending from the first side region, the second direction being perpendicular to the upper surface of the substrate.

5. The image sensor of claim 4, wherein
the second portion of the third insulating layer is on a first side of the first insulating layer in the first direction; and
the first insulating layer is directly in contact with the second impurity region on a second side of the first insulating layer in the first direction.

6. The image sensor of claim 1, wherein
the first impurity region and the second impurity region each have a thickness less than a thickness of the element isolation film in a second direction, the second direction perpendicular to the upper surface of the substrate.

7. The image sensor of claim 1, wherein
the first impurity region is doped with a P-type impurity; and
the second impurity region is doped with an N-type impurity.

8. The image sensor of claim 1, further comprising:
a first contact directly connected to the first impurity region; and
at least one second contact directly connected to the second impurity region.

9. The image sensor of claim 8, wherein
the substrate is a first substrate; and
the image sensor further includes,
a plurality of single photon avalanche diode (SPAD) pixels, each of the SPAD pixels including,
at least one semiconductor element connected to at least one photodiode, the first contact and the second contact, the at least one photodiode formed from the first impurity region and the second impurity region, and
the at least one semiconductor element is on a second substrate different from the first substrate.

10. The image sensor of claim 9, wherein
the first contact and the second contact are connected to a plurality of first pads;
the plurality of semiconductor elements are connected to a plurality of interconnection patterns and a plurality of second pads; and
the plurality of first pads and the plurality of second pads are in contact with each other.

11. The image sensor of claim 8, wherein
the first contact is configured to receive a first bias voltage;
the second contact is configured to receive a second bias voltage; and
the first bias voltage is lower than the second bias voltage.

12. The image sensor of claim 1, wherein each of the plurality of pixel areas further includes:
a first well region below the first impurity region in a second direction, the second direction perpendicular to the upper surface of the substrate;
a second well region below the second impurity region in the second direction; and
a third well region below the first well region and the second well region in the second direction.

13. The image sensor of claim 12, wherein
the first well region is doped with an impurity of the first conductivity-type, and the first well region has an impurity concentration lower than an impurity concentration of the first impurity region; and
the second well region and the third well region are doped with an impurity of the second conductivity-type, and the second well region and the third well region have an impurity concentration lower than an impurity concentration of the second impurity region.

14. The image sensor of claim 12, wherein at least a portion of the third well region overlaps the element isolation film in the second direction.

15. The image sensor of claim 12, wherein
each of the first well region and the second well region has a thickness greater than a thickness of the element isolation film in the second direction.

16. An image sensor comprising:
a substrate including a plurality of pixel areas;
a pixel isolation film disposed in the substrate, the pixel isolation film separating the plurality of pixel areas from each other;
each pixel area of the plurality of pixel areas including,
a first impurity region doped with an impurity of a first conductivity-type,
a second impurity region surrounding the first impurity region, the second impurity region doped with an impurity of a second conductivity-type different from the first conductivity-type, and
an element isolation film between the first impurity region and the second impurity region; and
the element isolation film has a first stack structure in a first direction different from a second stack structure of the element isolation film in a second direction, the first direction parallel to an upper surface of the substrate, and the second direction perpendicular to the upper surface of the substrate.

17. The image sensor of claim 16, wherein
the first stack structure of the element isolation film includes a first insulating layer, a second insulating layer, and a third insulating layer stacked in the first direction; and
the second stack structure of the element isolation film includes at least a portion of the first insulating layer and at least a portion of the third insulating layer stacked in the second direction.

18. The image sensor of claim 17, wherein the at least the portion of the third insulating layer is directly in contact with the at least the portion of the first insulating layer in the second direction.

19. The image sensor of claim 16, further comprising:
at least one single photon avalanche diode (SPAD) pixel, the at least one SPAD pixel formed from the first impurity region and the second impurity region, the first impurity region configured to be an anode of the SPAD pixel, and the second impurity region configured to be a cathode of the SPAD pixel.

20. An image sensor comprising:
a substrate including a plurality of pixel areas;
a pixel isolation film disposed in the substrate, the pixel isolation film separating the plurality of pixel areas from each other; and
each pixel area of the plurality of pixel areas includes,
a photodiode,
a plurality of semiconductor elements, and
an element isolation film between at least some of the plurality of semiconductor elements, the element isolation film including a first insulating layer, a second insulating layer, and a third insulating layer,
the first insulating layer in contact with the substrate,
the second insulating layer on the first insulating layer, the second insulating layer partially covering the first insulating layer, and the second insulating layer formed of a material different from a material of the first insulating layer, and
a portion of third insulating layer on the second insulating layer.
